(19) United States
(12) Patent Application Publication
(10) Pub. No.: US 2023/0260881 A1
(43) Pub. Date: Aug. 17, 2023

(54) SEMICONDUCTOR DEVICE AND METHOD FOR MAKING THE SAME

(71) Applicant: STATS ChipPAC Pte. Ltd, Singapore (SG)

(72) Inventors: HyunSeok PARK, Gyeonggi-do (KR); SinJae KIM, Gyeonggi-do (KR); YongMoo SHIN, Incheon (KR); DongJun SEO, Incheon (KR)

(21) Appl. No.: 18/163,884

(22) Filed: Feb. 3, 2023

(30) Foreign Application Priority Data
Feb. 11, 2022 (CN) 202210133245.6

(51) Int. Cl. H01L 23/498; H01L 23/31; H01L 25/16; H01L 21/60

(52) U.S. Cl. CPC H01L 23/49816; H01L 23/3128; H01L 25/16; H01L 21/60

(57) ABSTRACT

A semiconductor device and a method for making the same are provided. The method includes: providing a package including: a substrate including a first surface and a second surface opposite to the first surface; a first electronic component mounted on the first surface of the substrate; a conductive pillar formed on the first surface of the substrate, wherein a height of the conductive pillar is smaller than a height of the first electronic component; and a first encapsulant disposed on the first surface of the substrate and covering the first electronic component and the conductive pillar; forming a groove in the first encapsulant to expose a top surface and a portion of a lateral surface of the conductive pillar; and forming a bump in the groove, wherein the bump covers the top surface and the exposed portion of the lateral surface of the conductive pillar.

### TECHNICAL FIELD

The present application generally relates to semiconductor devices, and more particularly, to a semiconductor device and a method for making the same.

### BACKGROUND OF THE INVENTION

The semiconductor industry is constantly faced with complex integration challenges as consumers want their electronics to be smaller, faster and higher performance with more and more functionalities packed into a single device. One of the solutions is System-in-Package (SiP). SiP is a functional electronic system or sub-system that includes in a single package two or more heterogeneous semiconductor dice, such as a logic chip, a memory, integrated passive devices (IPD), RF filters, sensors, heat sinks, or antennas. Recently, SiP uses Double Side Molding (DSM) technology to further shrink the overall package size. However, semiconductor devices formed using the conventional DSM technology may have low reliability.

Therefore, a need exists for a high reliability semiconductor device.

### SUMMARY OF THE INVENTION

An objective of the present application is to provide a method for making a semiconductor device with high reliability.

According to an aspect of embodiments of the present application, a method for making a semiconductor device. The method may include: providing a package including: a substrate including a first surface and a second surface opposite to the first surface; a first electronic component mounted on the first surface of the substrate; a conductive pillar formed on the first surface of the substrate, wherein a height of the conductive pillar is smaller than a height of the first electronic component; and a first encapsulant disposed on the first surface of the substrate and covering the first electronic component and the conductive pillar; forming a groove in the first encapsulant to expose a top surface and a portion of a lateral surface of the conductive pillar; and forming a bump in the groove, wherein the bump covers the top surface and the exposed portion of the lateral surface of the conductive pillar.

According to another aspect of embodiments of the present application, a semiconductor device is provided. The device may include: a substrate including a first surface and a second surface opposite to the first surface; a first electronic component mounted on the first surface of the substrate; a conductive pillar formed on the first surface of the substrate, a height of the conductive pillar being smaller than a height of the first electronic component; a first encapsulant disposed on the first surface of the substrate and surrounding the first electronic component and the conductive pillar; a groove formed in the first encapsulant and exposing a top surface and a portion of a lateral surface of the conductive pillar; and a bump formed in the groove, wherein the bump covers the top surface and the exposed portion of the lateral surface of the conductive pillar.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A is a cross-sectional view illustrating a semiconductor device formed using a double side molding technology.

FIG. 1B is an enlarged view illustrating a portion of the semiconductor device of FIG. 1A.

FIG. 2A is a cross-sectional view illustrating a semiconductor device according to an embodiment of the present application.

FIG. 2B is an enlarged view illustrating a portion of the semiconductor device of FIG. 2A according to an embodiment of the present application.

FIG. 2C is an enlarged view illustrating a portion of the semiconductor device of FIG. 2A according to another embodiment of the present application.

FIG. 2D is an enlarged view illustrating a portion of the semiconductor device of FIG. 2A according to a further embodiment of the present application.

FIG. 3 is a flowchart illustrating a method for making a semiconductor device according to an embodiment of the present application.

FIGS. 4A to 4E are cross-sectional views illustrating various steps of the method for making a semiconductor device illustrated in FIG. 3 according to an embodiment of the present application.

FIGS. 5A to 5F are cross-sectional views illustrating various steps of making a package according to an embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

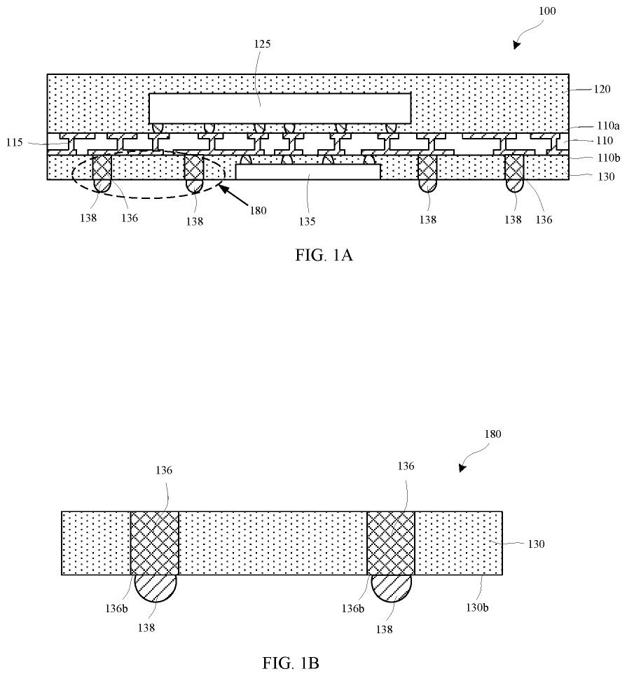

FIG. 1A illustrates a cross-sectional view of a semiconductor device 100 formed using a Double Side Molding (DSM) technology. FIG. 1B illustrates an enlarged view of a portion 180 of the semiconductor device 100 shown in FIG. 1A.

As shown in FIG. 1A, the semiconductor device 100 includes a substrate 110 with a top surface 110a and a bottom surface 110b which is opposite to the top surface 110a. A top electronic component 125 is mounted on the top surface 110a of the substrate 110, and a bottom electronic component 135 is mounted on the bottom surface 110b. A top encapsulant 120 is disposed on the top surface 110a and may cover the top electronic component 125 to protect against thermal shock, physical attach, fluid penetration, etc. Moreover, a bottom encapsulant 130 is disposed on the bottom surface 110b of the substrate 110 for similar protection purpose. One or more copper pillars 136 may be formed on the bottom surface 110b of the substrate 110 and electrically connected to respective conductive patterns or other similar structures. A bump 138 is further formed onto each copper pillar 136 to enable therethrough the connection of internal circuitry of the semiconductor device 100 with an exterior device or system.

Further referring to FIG. 1B, a bottom surface 136b of the copper pillar 136 and a bottom surface 130b of the bottom encapsulant 130 are at the same level relative to the bottom surface of the substrate 110. In an example, the copper pillar 136 and the bottom encapsulant 130 may be grinded simultaneously in a backgrinding process, and then solder paste 166 may be printed onto the bottom surface 136b of the copper pillar 136, and reflowed to form the bump 138. However, due to undesired oxidation during grinding or contaminations from the bottom encapsulant 130, the bottom surface 136b of the copper pillar 136 may exhibit poor wetting performance. Therefore, the bumps 138 may not cover the entire bottom surface 136b. Moreover, solder bridges may be formed over the bottom encapsulant 130 between two neighboring copper pillars 136, resulting in leakage issue of the semiconductor device 100.

To address at least one of the above problems, a semiconductor device is provided in an aspect of the present application. In the semiconductor device, one or more shorter copper pillars may be formed on a bottom surface of the substrate, that is, the copper pillars may be embedded inside a bottom encapsulant. A bowl-shaped groove may be formed in the bottom encapsulant and expose the bottom surface and a portion of a lateral surface of the copper pillar. Furthermore, the bump may be formed in the groove and cover the exposed bottom surface and lateral surface of the copper pillar. As more surface area of the copper pillar is covered by the bump, the adhesion between the copper pillar and the bump can be improved significantly. Moreover, as each bump is formed in a respective groove of the bottom encapsulant, the portion of the bottom encapsulant between two grooves can act as a barrier that prevents the formation of solder bridges. Thus, the reliability of the semiconductor device can be improved.

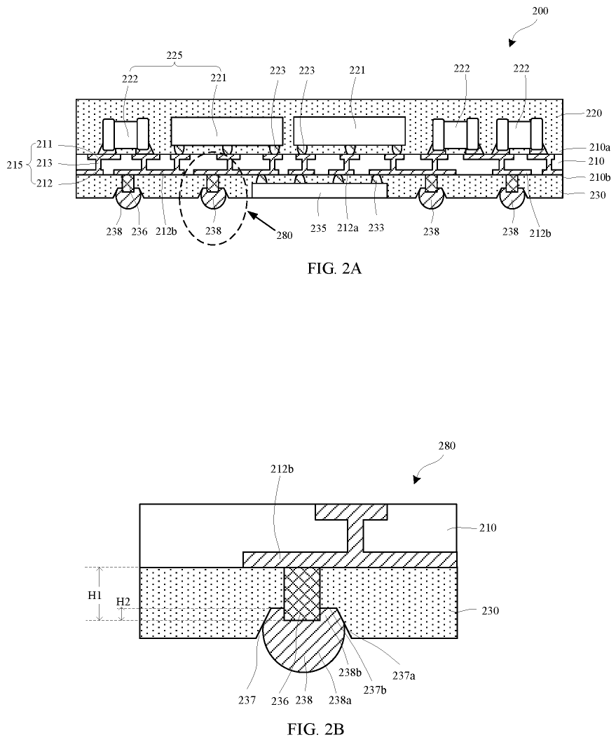

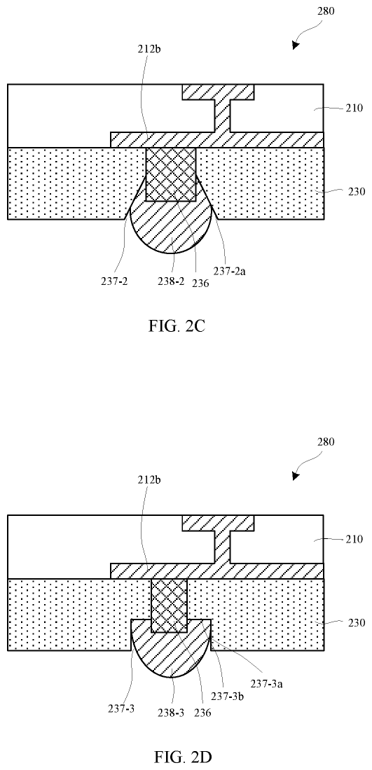

Referring to FIGS. 2A and 2B, a cross-sectional view of a semiconductor device 200 is illustrated according to an embodiment of the present disclosure. FIG. 2A illustrates a cross-sectional view of the semiconductor device 200, and FIG. 2B illustrates an enlarged view of a portion 280 of the semiconductor device 200 of FIG. 2A.

As illustrated in FIGS. 2A and 2B, the semiconductor device 200 may include a substrate 210, a top encapsulant 220, a top electronic component 225, a bottom encapsulant 230, a bottom electronic component 235, a conductive pillar 236 and a bump 238.

In particular, the substrate 210 has a top surface 210a and a bottom surface 210b. In some embodiments, the substrate 210 may include a redistribution structure (RDS) having one or more dielectric layers and one or more conductive layers between and through the dielectric layers. The conductive layers may define pads, traces and plugs through which electrical signals or voltages can be distributed horizontally and vertically across the RDS. As shown in the example of FIG. 2A, the RDS 215 may include a plurality of top conductive patterns 211 formed on the top surface 210a and a plurality of bottom conductive patterns 212 formed on the bottom surface 210b. In addition, the RDS 215 may further include one or more conductive vias 213 electrically connecting at least one of the top conductive patterns 211 formed on the top surface 210a with at least one of the bottom conductive patterns 212 formed on the bottom surface 210b. The RDS 215 may include one or more of Al, Cu, Sn, Ni, Au, Ag, or any other suitable electrically conductive material. In a case where the substrate 210 is a single layer, the conductive vias 213 may penetrate between the top surface 210a and the bottom surface 210b to directly connect the top conductive patterns 211 with the bottom conductive patterns 212 respectively. In a case where the substrate 210 has multiple layers, the conductive vias 213 may be configured to partially penetrate between the top surface 210a and the bottom surface 210b to connect the top conductive patterns 211 and the bottom conductive patterns 212 using additional wire patterns formed within the substrate 210. It could be appreciated that, the top conductive patterns 211, the bottom conductive patterns 212 and the conductive vias 213 may be implemented in various structures and types, but aspects of the present application are not limited thereto.

The top electronic component 225 may be mounted on the top surface 210a of the substrate 210 and electrically connected to one or more of the top conductive patterns 211. In the example of FIG. 2A, the top electronic component 225 may include semiconductor dice 221 and discrete devices 222. In FIG. 2A, the semiconductor dice 221 are formed in a flip chip type and may be mounted such that conductive bumps 223 of the semiconductor dice 221 are welded to some of the top conductive patterns 211. In other embodiments, the semiconductor dice 221 may include bond pads and may be connected to the top conductive patterns 211 by wire bonding. The present application does not limit the connection between the semiconductor dice 221 and the top conductive patterns 211 to that disclosed herein.

The bottom electronic component 235 may be mounted on the bottom surface 210b of the substrate 210 and electrically connected to one or more of the bottom conductive patterns 212. In the example of FIG. 2A, the bottom electronic component 235 is shown as a semiconductor die. In other embodiments, the bottom electronic component 235 may include a plurality of semiconductor dice or may further include one or more discrete devices, but aspects of the present application are not limited thereto. The bottom electronic component 235 is attached to a part of the plurality of bottom conductive patterns 212a, while exposes the remaining of the plurality of bottom conductive patterns 212b. These exposed or uncovered bottom conductive patterns 212b can ensure that the electrical connection to the top electronic component 225 is available to the exterior environment, which may be subsequently connected with a bump, and may be referred to as contact pads hereinafter.

As aforementioned, the top electronic component 225 or the bottom electronic component 235 may include a semiconductor die or a discrete device. In an example, the top electronic component 225 and the bottom electronic component 235 may include one or more transistors, or may include a microcontroller device, a radio-frequency (RF) device, a wireless (WiFi, WLAN, etc.) switch, a power amplifier device, a low noise amplifier (LNA) device, etc.

The top encapsulant 220 may be disposed on the top surface 210a of the substrate 210 and cover the top electronic component 225. The top encapsulant 220 may be made of a general molding compound resin, for example, an epoxy-based resin, but the scope of this application is not limited thereto. The top encapsulant 220 may protect the top electronic component 225 from external environment.

The bottom encapsulant 230 may be disposed on the bottom surface 210b of the substrate 210 and may surround the bottom electronic component 235 and the conductive pillar 236. The conductive pillar 236 may include one or more of Al, Cu, Sn, Ni, Au, Ag, or other suitable electrically conductive material. In an example, the conductive pillar 236 is a copper pillar, but aspects of the present disclosure are not limited thereto. In the example, a height of the conductive pillar 236 is smaller than a height of the bottom electronic component 235, and thus, when viewed from the bottom surface 210b, the bottom surface of the bottom encapsulant 230 is coplanar with the bottom surface of the bottom electronic component 235, but is lower than the bottom surface of the conductive pillar 236. In some embodiments, the height of the conductive pillar 236 may range from 10% to 90% of the height of the bottom electronic component 235, for example, 20%, 30%, 40%, 50%, 60%, 70% or 80% of the height of the bottom electronic component 235. The bottom encapsulant 230 and the top encapsulant 220 may be made of the same material, for example, an epoxy-based resin. In this way, such shorter conductive pillar 236 may not be exposed from the bottom encapsulant 230 when the excess bottom encapsulant 230 covering the bottom electronic component 235 is not removed, avoiding undesired oxidation of the conductive pillar 236.

Further referring to FIG. 2B, a groove 237 may be formed in the bottom encapsulant 230 and may expose the bottom surface and a portion of a lateral surface of the conductive pillar 236 adjacent to the bottom surface of the conductive pillar 236. The groove 237 may be formed using a laser ablation process, for example. In some embodiments, a height H2 of the exposed portion of the lateral surface of the conductive pillar 236 ranges from 10% to 90% of the total height H1 of the conductive pillar 236, for example, 20%, 30%, 40%, 50%, 60%, 70% or 80% of the total height of the conductive pillar 236. A bump 238 may be formed in the groove, and may cover the bottom surface and the exposed lateral surface of the conductive pillar 236. The bump 238 and the conductive pillar 236 look like a match head and a match stick. As shown in FIG. 2B, the bump 238 includes a main body 238a and a filler portion 238b. In particular, the main body 238a of the bump 238 covers the bottom surface of the conductive pillar 236, and the filler portion 238b of the bump 238 fills between the exposed lateral surface of the conductive pillar 236 and the groove 237. The top surface of the conductive pillar 236 may be connected to the bottom conductive pattern 212, and the bottom surface of the conductive pillar 236 may be connected to the bump 238. That is to say, the conductive pillar 236 may electrically connect the bump 238 with the bottom conductive pattern 212 formed on the substrate 210. In a case where the semiconductor device 200 is further connected to an external device, such as a motherboard, the bump 238 may be used in electrically connecting the semiconductor device 200 to the external device.

In the example shown in FIG. 2B, the groove 237 generally has a truncated shape with a trapezoidal cross section, and includes a groove wall 237a and a base 237b. The groove wall 237a may have an acute angle relative to the bottom surface of the bottom encapsulant 230, while the base 237b may be substantially parallel to the bottom surface of the bottom encapsulant 230. The width of the base 237b is greater than the width of the conductive pillar 236, and accordingly the filler portion 238b of the bump 238 formed on the base 237b can surround the exposed portion of the lateral surface of the conductive pillar 236.

FIG. 2C illustrates an enlarged view of the portion 280 of the semiconductor device 200 of FIG. 2A according to another embodiment. As illustrated in FIG. 2C, the groove 237-2 only includes a conical groove wall 237-2a, and no flat base (e.g., the base 237b shown in FIG. 2B) is formed between the groove wall 237-2a and the conductive pillar 236. Still, the depth of the groove 237-2 is bigger than a depth of the bottom surface of the conductive pillar 236 such that at least a portion of the lateral surface of the conductive pillar 236 is exposed.

FIG. 2D illustrates an enlarged view of the portion 280 of the semiconductor device 200 of FIG. 2A according to a further embodiment. As illustrated in FIG. 2D, the groove 237-3 generally has a cylindrical shape, and includes a groove wall 237-3a and a base 237-3b. Different from the inclined groove walls shown in FIGS. 2B and 2C, the groove wall 237-3a shown in FIG. 2D may be vertical to the bottom surface of the bottom encapsulant 230. In this way, more bump material may be formed within the groove 237-3, thereby further enhancing the adhesion of the bump 238-3 to the conductive pillar 236.

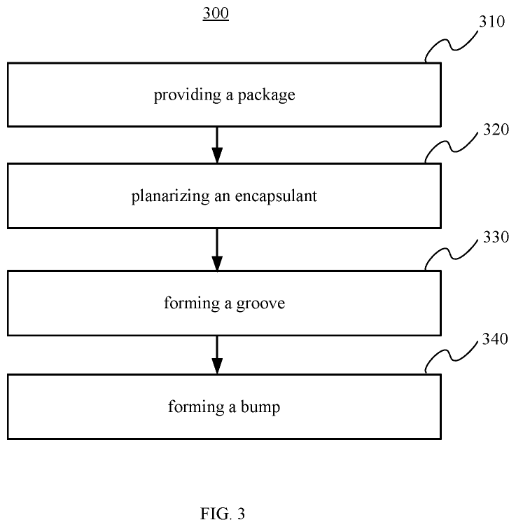

Referring to FIG. 3, a flowchart illustrating a method 300 for making a semiconductor device is illustrated according to an embodiment of the present application. For example, the method 300 may be used to make the semiconductor device shown in FIG. 2A.

As illustrated in FIG. 3, the method 300 may start with providing a package in block 310. In some embodiments, the package may be an integrated circuit package, with some package materials enclosing one or more semiconductor dice, for example. In block 320, an encapsulant of the package may be planarized. Afterwards, a groove may be formed in the encapsulant in block 330, and a bump may be formed in the groove in block 340.

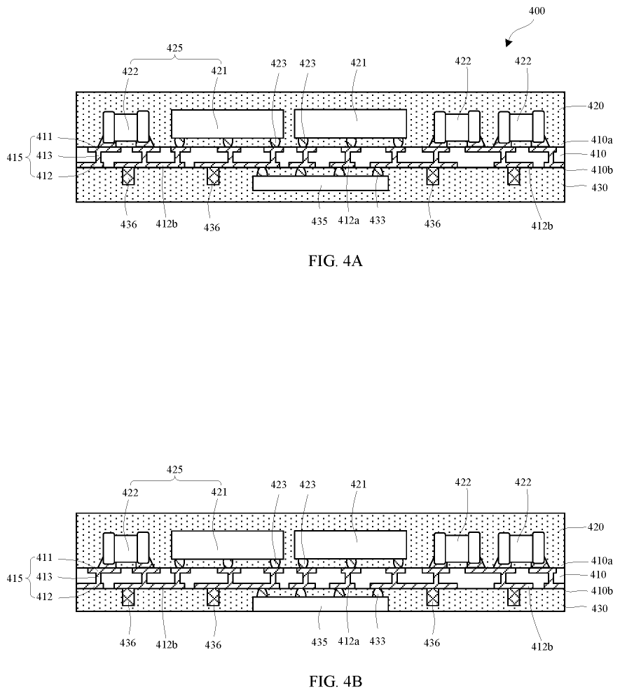

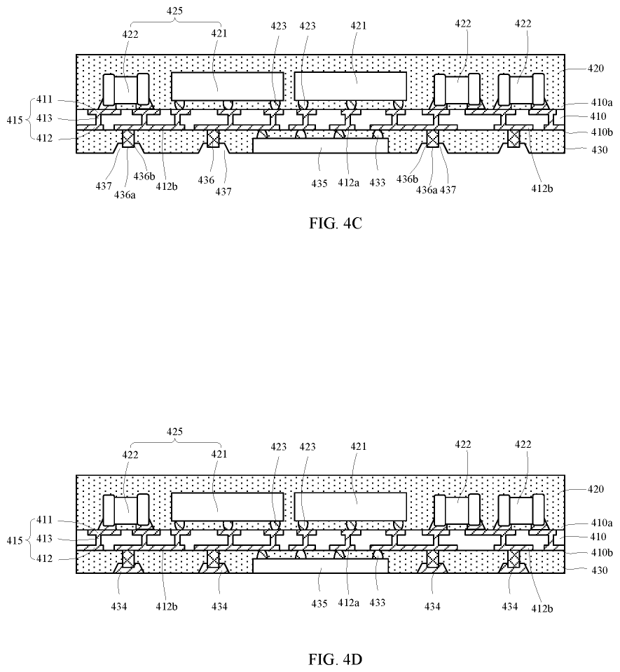

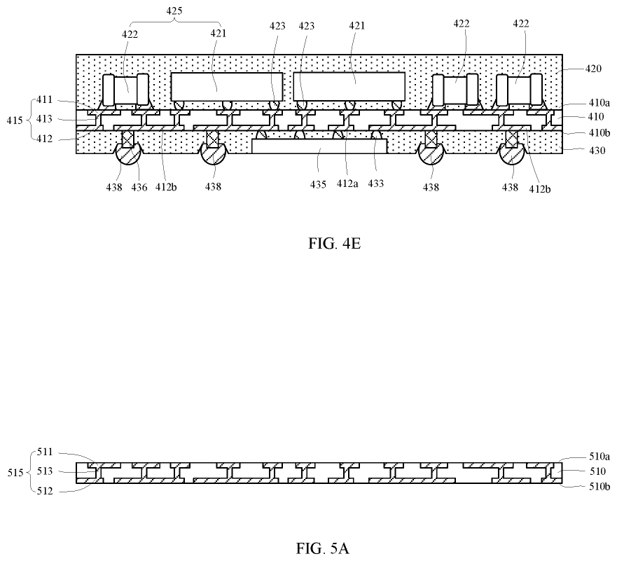

Referring to FIGS. 4A to 4E, cross-sectional views illustrating various blocks of the method for making a semiconductor device are illustrated. In the following, the method 300 of FIG. 3 will be described with references to FIGS. 4A to 4E in more details.

As illustrated in FIG. 4A, a package 400 is provided. The package 400 may include a substrate 410, a top encapsulant 420, top electronic component(s) 425, a bottom encapsulant 430, a bottom electronic component 435, and one or more conductive pillars 436.

The substrate 410 has a top surface 410a and a bottom surface 410b. A redistribution structure (RDS) 415 is formed in the substrate 410, which include a plurality of top conductive patterns 411, a plurality of bottom conductive patterns 412, and a plurality of conductive vias 413 electrically connecting at least one of the top conductive patterns 411 with at least one of the bottom conductive patterns 412. The top electronic component 425 is mounted on the top surface 410a of the substrate 410 and is electrically connected to the top conductive patterns 411. The top encapsulant 420 is disposed on the top surface 410a of the substrate 410 and covers the top electronic component 425. The bottom electronic component 435 is mounted on the bottom surface 410b of the substrate 410 and is electrically connected to the bottom conductive patterns 412. The conductive pillars 436 are also formed on the bottom surface 410b of the substrate 410 and are electrically connected to the bottom conductive patterns 412. The height of each conductive pillar 436 may be smaller than a height of the bottom electronic component 435 relative to the bottom surface 410b. In some embodiments, the height of the conductive pillar 436 may range from 10% to 90% of the height of the bottom electronic component 435, for example, 20%, 30%, 40%, 50%, 60%, 70%, 80%, etc. The bottom encapsulant 430 is disposed on the bottom surface 410b of the substrate 410 and covers the bottom electronic component 435 and the conductive pillar 436. In some embodiments, the heights of the conductive pillars 436 may be the same as each other, or may be different from each other.

As illustrated in FIG. 4B, the bottom encapsulant 430 is planarized to expose the bottom electronic component 435. In some embodiments, a backgrinding operation with grinder, or another suitable chemical or mechanical grinding or etching process, can be used to reduce a thickness of the bottom encapsulant 430 and expose the bottom electronic component 435. The planarization may result in that a surface of the bottom encapsulant 430 is coplanar with a surface of the bottom electronic component 435 by removing portions of the bottom encapsulant 430. As the height of the conductive pillar 436 is smaller than the height of the bottom electronic component 435, the conductive pillar 436 is still covered by the bottom encapsulant 430 after the planarization. Thus, the conductive pillar 436 may not be oxidized or contaminated. In some embodiments, respective distances from the conductive pillars 436 to the bottom electronic component 435 or any other anchor structure that is exposed after planarization may be measured in advance, such that the positions of the conductive pillars 436 can be accurately determined based on the position of the anchor structure, even if they are not exposed after planarization. In other embodiments, after the bottom encapsulant 430 is planarized or thinned, the bottom electronic components 435 may still be covered by the bottom encapsulant 430, but is not exposed from the bottom encapsulant 430.

Afterwards, as illustrated in FIG. 4C, a groove 437 is formed in the bottom encapsulant 430 to expose a bottom surface 436a and a portion of a lateral surface 436b of the conductive pillar 436. In some embodiments, a height of the exposed lateral surface 436b of the conductive pillar 436 ranges from 10% to 90% of the total height of the conductive pillar 436, for example, 20%, 30%, 40%, 50%, 60%, 70% or 80% of the total height of the conductive pillar 436. The bottom surface 436a and the portion of the lateral surface 436b exposed from the bottom encapsulant 430 can provide a larger contacting surface for a bump formed in subsequent steps, and thus the adhesion between the conductive pillar 436 and the bump can be improved significantly.

In some embodiments, a laser ablation process may be employed to form the groove 437 in the bottom encapsulant 430. In addition, the groove 437 may be formed by an etching process, or any other process known in the art so long as the encapsulant material can be removed. In some embodiments, after forming the groove 437, a cleaning process for removing residuals may further be performed. For example, a masking layer with openings corresponding to the conductive pillars 436 may be deposited on the bottom encapsulant 430, and then the encapsulant material exposed from the opening of the masking layer can be removed to expose a bottom surface 436a and a portion of a lateral surface 436b of the conductive pillar 436.

In some embodiments, the groove 437 may encircle the conductive pillar 436, i.e., a full periphery of the conductive pillar 436 may be exposed. In other embodiments, the groove 437 may encircle in part the lateral surface of the conductive pillar 436. In general, a width of the groove 437 may be larger than a diameter of the conductive pillar 436, so as to facilitate subsequent bump formation steps and realize better electrical performance.

More details about configurations of the groove 437 may refer to FIGS. 2B-2D and relevant descriptions in above embodiments, and will not be elaborated herein.

As illustrated in FIG. 4D, an electrically conductive bump material 434 may be deposited in the groove of the bottom encapsulant 430 using one of or any combination of the following processes: evaporation, electrolytic plating, electroless plating, ball drop, or screen printing process. The conductive bump material 434 may include Al, Sn, Ni, Au, Ag, lead (Pb), bismuth (Bi), Cu, solder, and combinations thereof, with an optional flux solution. For example, the conductive bump material 434 can be solder paste, and the solder paste is printed in the groove of the bottom encapsulant 430. As the conductive bump material 434 is deposited in the groove of the bottom encapsulant 430, the portion of the bottom encapsulant 430 between two grooves can act as a barrier that prevents the formation of solder bridges.

As illustrated in FIG. 4E, a bump 438 is formed in the groove of the bottom encapsulant 430. The bump material may be bonded to the conductive pillar 436 using a suitable attachment or bonding process. In an embodiment, the bump material may be reflowed by heating the material above its melting point to form conductive balls or bump 438. The bump 438 may cover the bottom surface and the exposed lateral surface of the conductive pillar 436. The bump 438 may protrude from the bottom surface of the bottom encapsulant 430. As the conductive pillar 436 is covered by the bottom encapsulant 430 and is not oxidized or contaminated in the planarization process, the bottom surface and the exposed lateral surface of the conductive pillar 436 can exhibit better wetting performance, and the bump 438 can cover the entire surface of the conductive pillar 436 exposed from the bottom encapsulant 430.

In some applications, the bump 438 can also be compression bonded or thermocompression bonded to the conductive pillar 436. In a case that the conductive bump material includes flux solution, a deflux operation may be further performed to clean the flux solution. The hemispherical bump 438 shown in FIG. 4E may represent one type of interconnect structure that can be formed over the conductive pillar 436. In other examples, the bump 438 may be a stud bump, a micro bump, or other electrical interconnects.

More details about configurations of the bump 438 may refer to FIGS. 2B-2D and relevant descriptions in above embodiments, and will not be elaborated herein.

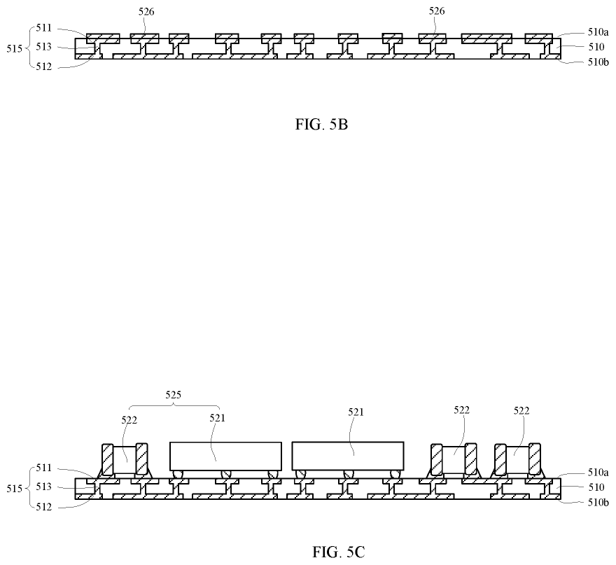

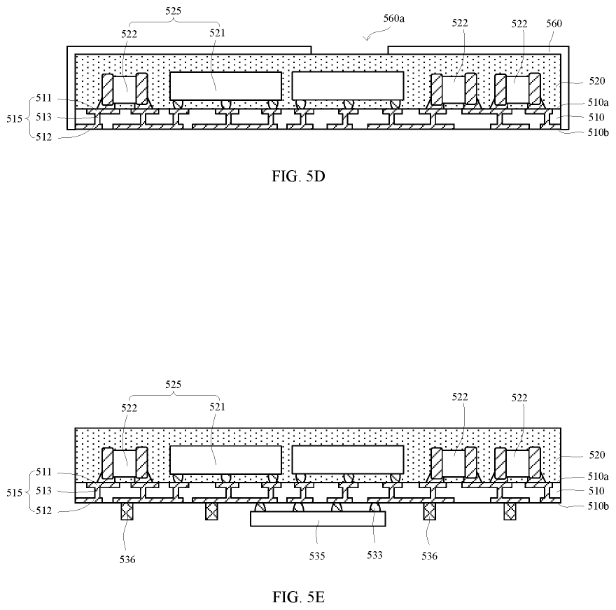

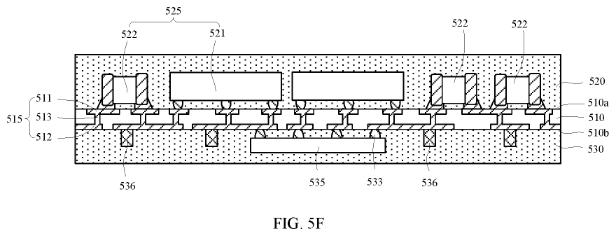

FIGS. 5A-5F illustrate a process for making a package according to an embodiment of the present application. The package may be the same as or similar to the package 400 of FIG. 4A. It can be appreciated that packages with similar topography can be formed using this process.

In particular, the process starts with providing a package substrate 510 as illustrated in FIG. 5A. The substrate 510 can be a laminate interposer, PCB, wafer-form, strip interposer, leadframe, or another suitable substrate. The substrate 510 may include one or more insulating or passivation layers, one or more conductive vias formed through the insulating layers, and one or more conductive layers formed over or between the insulating layers. The substrate 510 may include one or more laminated layers of polytetrafluoroethylene pre-impregnated, FR-4, FR-1, CEM-1, or CEM-3 with a combination of phenolic cotton paper, epoxy, resin, woven glass, matte glass, polyester, and other reinforcement fibers or fabrics. The insulating layers may contain one or more layers of silicon dioxide (SiO₂), silicon nitride (Si₃N₄), silicon oxynitride (SiON), tantalum pentoxide (Ta₂O₅), aluminum oxide (Al₂O₃), or other material having similar insulating and structural properties. The substrate 510 can also be a multi-layer flexible laminate, ceramic, copper clad laminate, glass, or semiconductor wafer including an active surface containing one or more transistors, diodes, and other circuit elements to implement analog circuits or digital circuits. The substrate 510 may include one or more electrically conductive layers or redistribution layers (RDL) formed using sputtering, electrolytic plating, electroless plating, or other suitable deposition process. The conductive layers may be one or more layers of Al, Cu, Sn, Ni, Au, Ag, titanium (Ti), tungsten (W), or other suitable electrically conductive material.

In the example shown in FIG. 5A, only one insulating layer is illustrated as a core substrate, a plurality of top conductive patterns 511 are formed on the top surface 510a of the substrate 510, and a plurality of bottom conductive patterns 512 are formed on the bottom surface 510b of the substrate 510. At least one of the plurality of top conductive patterns 511 and at least one of the plurality of bottom conductive patterns 512 are electrically connected respectively by a plurality of conductive vias 513 formed in the insulating layer. In some alternative embodiments, additional insulating layers and/or conductive layers may be formed over the structure shown in FIG. 5A to implement more advanced signal routing.

As shown in FIG. 5B, solder paste 526 may be deposited or printed onto the top conductive patterns 511 at locations where devices are to be surface mounted onto the top surface 510a of the substrate 510. The solder paste 526 can be dispensed by jet printing, laser printing, pneumatically, by pin transfer, using a photoresist mask, by stencil-printing, or by another suitable process.

As shown in FIG. 5C, the top electronic component 525 may be disposed over the top surface 510a with terminals of the top electronic component 525 in contact with and over the solder paste 526. The top electronic component 525 may include semiconductor dice 521 and discrete devices 522. The top electronic component 525 may be passive or active devices as desired to implement any given electrical functionality within the semiconductor package being formed. The top electronic component 525 may be active devices such as semiconductor dice, semiconductor packages, discrete transistors, discrete diodes, etc. The top electronic component 525 may also be passive devices such as capacitors, inductors, or resistors. Then, the solder paste 526 may be reflowed to mechanically and electrically couple the top electronic component 525 to the top conductive patterns 511.

As shown in FIG. 5D, a top encapsulant 520 may be formed on the top surface 510a of the substrate 510 to cover the top electronic component 525. The top encapsulant 520 may be formed using a paste printing, compressive molding, transfer molding, liquid encapsulant molding, vacuum lamination, spin coating, or other suitable applicator. In an example, the substrate 510 with the top electronic component 525 is disposed within a mold 560. The mold 560 may include one or more inlet ports 560a formed in its top plate or side plate. The inlet port 560a is used for injection of encapsulant into the mold 560. The top encapsulant 520 is injected into the mold 560 through the inlet port 560a. The top encapsulant 520 fully covers the semiconductor dice 521 and the discrete devices 522. The top encapsulant 520 may be polymer composite material, such as epoxy resin with filler, epoxy acrylate with filler, or polymer with proper filler. The top encapsulant 520 may be non-conductive and environmentally protects the semiconductor device from external elements and contaminants. The top encapsulant 520 may also protect the top electronic component 525 from degradation due to exposure to light. In some examples, the top encapsulant 520 may be planarized after removed from the mold 560, if desired.

As shown in FIG. 5E, a bottom electronic component 535 and a conductive pillar 536 is formed on the bottom surface. For example, the substrate 510 is flipped with the bottom surface 510b oriented upward. Solder paste is patterned onto parts of the bottom conductive patterns 512 on the bottom surface 510b of the substrate 510, and the bottom electronic component 535 is surface mounted on the bottom surface 510b through the solder paste. In the example of FIG. 5E, the bottom electronic component 535 is shown as a semiconductor die. In some other embodiments, a plurality of semiconductor dice or one or more discrete devices can be surface mounted on the bottom surface 510b through the solder paste. Besides, the conductive pillar 536 are formed on the bottom conductive patterns 512 on the bottom surface 510b of the substrate 510. For example, the conductive pillar 536 are formed by depositing one or more layers of conductive material into openings of a masking layer. In other embodiments, conductive pillars 536 are formed by another suitable metal deposition technique.

As shown in FIG. 5F, the bottom encapsulant 530 is formed on the bottom surface 510b of the substrate 510 to cover the bottom electronic component 535 and the conductive pillar 536. The bottom encapsulant 530 may be formed using a paste printing, compressive molding, transfer molding, liquid encapsulant molding, vacuum lamination, spin coating, or other suitable applicator. The bottom encapsulant 530 and the top encapsulant 520 may be made of the same material, for example, an epoxy-based resin. In some examples, the bottom encapsulant 530 may be planarized after removed from the mold, if desired.

While the process for making the package same or similar to the package 400 of FIG. 4A is illustrated in conjunction with FIGS. 5A-5F, it will be appreciated by those skilled in the art that modifications and adaptations to the process may be made without departing from the scope of the present invention.

The discussion herein included numerous illustrative figures that showed various portions of an electronic package assembly and method of manufacturing thereof. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for making a semiconductor device, comprising:
providing a package comprising:
a substrate comprising a first surface and a second surface opposite to the first surface;
a first electronic component mounted on the first surface of the substrate;
a conductive pillar formed on the first surface of the substrate, wherein a height of the conductive pillar is smaller than a height of the first electronic component; and
a first encapsulant disposed on the first surface of the substrate and covering the first electronic component and the conductive pillar;
forming a groove in the first encapsulant to expose a top surface and a portion of a lateral surface of the conductive pillar; and
forming a bump in the groove, wherein the bump covers the top surface and the exposed portion of the lateral surface of the conductive pillar.

2. The method of claim 1, wherein the height of the conductive pillar ranges from 10% to 90% of the height of the first electronic component.

3. The method of claim 1, wherein the bump comprises a main body and a filler portion, the main body of the bump covers the top surface of the conductive pillar, and the filler portion of the bump covers the portion of the lateral surface of the conductive pillar exposed from the first encapsulant.

4. The method of claim 1, wherein a height of the exposed portion of the lateral surface of the conductive pillar ranges from 10% to 90% of the height of the conductive pillar.

5. The method of claim 1, further comprising:
planarizing the first encapsulant to expose the first electronic component before forming the groove in the first encapsulant.

6. The method of claim 1, wherein forming the groove in the first encapsulant comprises forming the groove in the first encapsulant using a laser ablation process.

7. The method of claim 1, wherein the groove partially or totally surrounds the conductive pillar.

8. The method of claim 1, wherein forming the bump in the groove comprises:
printing solder paste in the groove of the first encapsulant; and
reflowing the solder paste to form the bump.

9. The method of claim 1, wherein the conductive pillar comprises a copper pillar.

10. The method of claim 1, wherein the conductive pillar is outside the first electronic component on the first surface of the substrate.

11. The method of claim 1, wherein the package further comprises:
a second electronic component mounted on the second surface of the substrate; and
a second encapsulant disposed on the second surface of the substrate and covering the second electronic component.

12. A semiconductor device, comprising:
a substrate comprising a first surface and a second surface opposite to the first surface;
a first electronic component mounted on the first surface of the substrate;
a conductive pillar formed on the first surface of the substrate, a height of the conductive pillar being smaller than a height of the first electronic component;
a first encapsulant disposed on the first surface of the substrate and surrounding the first electronic component and the conductive pillar;
a groove formed in the first encapsulant and exposing a top surface and a portion of a lateral surface of the conductive pillar; and
a bump formed in the groove, wherein the bump covers the top surface and the exposed portion of the lateral surface of the conductive pillar.

13. The semiconductor device of claim 12, wherein the height of the conductive pillar ranges from 10% to 90% of the height of the first electronic component.

14. The semiconductor device of claim 12, wherein the bump comprises a main body and a filler portion, the main body of the bump covers the top surface of the conductive pillar, and the filler portion of the bump covers the portion of the lateral surface of the conductive pillar exposed from the first encapsulant.

15. The semiconductor device of claim 12, wherein a height of the exposed portion of the lateral surface of the conductive pillar ranges from 10% to 90% of the height of the conductive pillar.

16. The semiconductor device of claim 12, wherein the first encapsulant exposes a top surface of the first electronic component.

17. The semiconductor device of claim 12, wherein the groove partially or totally surrounds the conductive pillar.

18. The semiconductor device of claim 12, wherein the conductive pillar comprises a copper pillar.

19. The semiconductor device of claim 12, wherein the conductive pillar is outside the first electronic component on the first surface of the substrate.

20. The semiconductor device of claim 12, further comprising:
a second electronic component mounted on the second surface of the substrate; and
a second encapsulant disposed on the second surface of the substrate and covering the second electronic component.
